(19) United States
(12) Patent Application Publication
(10) Pub. No.: US 2024/0052239 A1
(43) Pub. Date: Feb. 15, 2024

(54) Quantum Dot, Optical Member Including Quantum Dot, Electronic Apparatus Including Quantum Dot, and method of Preparing Quantum Dot

(71) Applicant: Samsung Display Co., Ltd., Yongin-si, Gyeonggi-do (KR)

(72) Inventors: Jungho JO, Yongin-si (KR); Yunhyuk KO, Yongin-si (KR); Yunku JUNG, Yongin-si (KR); Changyeol HAN, Yongin-si (KR)

(21) Appl. No.: 18/344,540

(22) Filed: Jun. 29, 2023

(30) Foreign Application Priority Data
Jul. 4, 2022 (KR) 10-2022-0082137

(51) Int. Cl. C09K 11/62; H10K 50/115; C09K 11/58; C09K 11/02

(52) U.S. Cl. CPC C09K 11/621; H10K 50/115; C09K 11/586; C09K 11/02; H10K 2102/331

(57) ABSTRACT

A quantum dot may include a core including indium (In) and A¹, and a first shell covering the core, wherein A¹ may be a group III element other than indium, a ratio of a radius of the core to a thickness of the first shell may be in a range of about 1:1 to about 9:1, and the quantum dot may emit blue light having a maximum emission wavelength in a range of about 440 nanometers (nm) to about 480 nm.

### CROSS-REFERENCE TO RELATED APPLICATION

This application claims priority to and the benefit of Korean Patent Application No. 10-2022-0082137, filed on Jul. 4, 2022, in the Korean Intellectual Property Office, the entire content of which is incorporated herein by reference.

### BACKGROUND

### 1. Field

One or more aspects of embodiments of the present disclosure relate to a quantum dot, an optical member including the quantum dot, an electronic apparatus including the quantum dot, and a method of preparing the quantum dot.

### 2. Description of the Related Art

Quantum dots may be used as materials that perform various optical functions (for example, a light conversion function, a light emission function, and/or the like) in optical members and various electronic apparatuses. Quantum dots, which are semiconductor nanocrystals with a quantum confinement effect, may have different energy bandgaps by controlling (e.g., adjusting) of the size and composition of the nanocrystals, and thus may emit light of various emission wavelengths.

An optical member including such quantum dots may have the form of a thin film, for example, a thin film patterned for each sub-pixel. Such an optical member may be used as a color conversion member of a device including one or more suitable light sources.

Quantum dots may be used for a variety of purposes in various suitable electronic apparatuses. For example, quantum dots may be used as emitters. Here, for example, quantum dots may be included in an emission layer of a light-emitting device including a pair of electrodes and the emission layer, and may serve as the emitters.

Currently, to implement high-definition optical members and electronic apparatuses, there is a need (or desire) for the development of quantum dots that emit blue light, have high photoluminescence quantum yield (PLQY), and do not include possible toxic elements, such as, e.g., cadmium.

### SUMMARY

One or more aspects of embodiments of the present disclosure are directed toward a novel quantum dot, an optical member including the quantum dot, an electronic apparatus including the quantum dot, and a method of preparing the quantum dot.

Additional aspects will be set forth in part in the description which follows and, in part, will be apparent from the description, or may be learned by practice of the presented embodiments of the disclosure.

According to one or more embodiments,
a quantum dot may include a core including indium (In) and A¹, and
a first shell covering the core,
wherein A¹ may be a group III element other than indium,
a ratio of a radius of the core to a thickness of the first shell may be in a range of about 1:1 to about 9:1, and
the quantum dot may emit blue light having a maximum emission wavelength in a range of about 440 nanometers (nm) to about 480 nm.

According to one or more embodiments, an optical member may include the quantum dot.

According to one or more embodiments, an electronic apparatus may include the quantum dot.

According to one or more embodiments, a method of preparing the quantum dot may include mixing a first precursor including indium (In) with a second precursor including A¹ to prepare a core, and mixing a third precursor including A³ with a fourth precursor including B² to prepare a first shell,
wherein a molar ratio of the second precursor to the third precursor may be 1:5.2 or greater.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a quantum dot according to one or more embodiments;

FIG. 2 is a schematic view of an electronic apparatus according to one or more embodiments;

FIG. 3 is a schematic view of an electronic apparatus according to one or more embodiments;

FIG. 4 is a graph showing photoluminescence spectra of Example 1 and Comparative Examples 1, 2 and 4; and

FIG. 5 shows transmission electron microscope (TEM) images of Examples 1 and 2 and Comparative Example 3.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the term “and/or” includes any and all combinations of one or more of the associated listed items.

As used herein, expressions such as “at least one of”, “one of”, and “selected from”, when preceding a list of elements, modify the entire list of elements and do not modify the individual elements of the list. Throughout the disclosure, the expression “at least one of a, b or c,” “at least one selected from a, b and c”, and “at least one of a, b and/or c” indicates only a, only b, only c, both (e.g., simultaneously) a and b, both (e.g., simultaneously) a and c, both (e.g., simultaneously) b and c, all of a, b, and c, or variations thereof.

As the disclosure allows for various changes and numerous embodiments, particular embodiments will be illustrated in the drawings and described in more detail in the written description. Effects, features, and a method of achieving the disclosure will be obvious by referring to example embodiments of the disclosure with reference to the attached drawings. The disclosure may, however, be embodied in many different forms and should not be construed as being limited to the embodiments set forth herein.

It will be understood that, although the terms first, second, etc. may be used herein to describe various elements, these elements should not be limited by these terms. These terms are only used to distinguish one element from another.

In the embodiments described in the present specification, an expression used in the singular encompasses the expression of the plural, unless it has a clearly different meaning in the context.

In the present specification, it is to be understood that the terms such as “including,” “having,” and “comprising” are intended to indicate the existence of the features or components disclosed in the specification, and are not intended to preclude the possibility that one or more other features or components may exist or may be added. For example, unless otherwise limited, terms such as “including” or “having” may refer to either consisting of features or components described in the specification only or further including other components.

As used herein, the terms “use,” “using,” and “used” may be considered synonymous with the terms “utilize,” “utilizing,” and “utilized,” respectively.

The use of “may” when describing embodiments of the present disclosure refers to “one or more embodiments of the present disclosure”.

It will be understood that when an element is referred to as being “on,” “connected to,” or “coupled to” another element, it may be directly on, connected, or coupled to the other element or one or more intervening elements may also be present. When an element is referred to as being “directly on,” “directly connected to,” or “directly coupled to” another element, there are no intervening elements present.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic apparatus and/or any other relevant devices or components according to embodiments of the present invention described herein may be implemented utilizing any suitable hardware, firmware (e.g. an application-specific integrated circuit), software, or a combination of software, firmware, and hardware. For example, the various components of the apparatus may be formed on one integrated circuit (IC) chip or on separate IC chips. Further, the various components of the apparatus may be implemented on a flexible printed circuit film, a tape carrier package (TCP), a printed circuit board (PCB), or formed on one substrate. Further, the various components of the apparatus may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The term “group I” used herein may include a group IA element and a group IB element on the IUPAC periodic table, and the group I element may include, for example, silver (Ag) and/or copper (Cu).

The term “group II” used herein may include a group IIA element and a group IIB element on the IUPAC periodic table, and the group II element includes, for example, magnesium (Mg), calcium (Ca), zinc (Zn), cadmium (Cd), and/or mercury (Hg).

The term “group III” used herein may include a group IIIA element and a group IIIB element on the IUPAC periodic table, and the group III element may include, for example, aluminum (Al), gallium (Ga), indium (In), and/or thallium (Tl).

The term “group VI” used herein may include a group VIA element and a group VIB element on the IUPAC periodic table, and the group VI element may include, for example, oxygen (O), sulfur (S), selenium (Se), and/or tellurium (Te).

The term “average diameter (D50)” used herein refers to a particle size corresponding to 50% of a weight percentage on a particle size distribution curve, For example, a particle size at which a passing mass percentage is 50%. The average particle size D50 may be measured by a suitable technique, e.g., using a particle size analyzer, transmission electron microscope photography, and/or scanning electron microscope photography. Another method may be performed by using a measuring device with dynamic light scattering, analyzing data to count a number of particles relative to each particle size, and then calculating to obtain an average particle diameter D50. In the present specification, when particles are spherical, “diameter” indicates a particle diameter, and when the particles are non-spherical, the “diameter” indicates a major axis length.

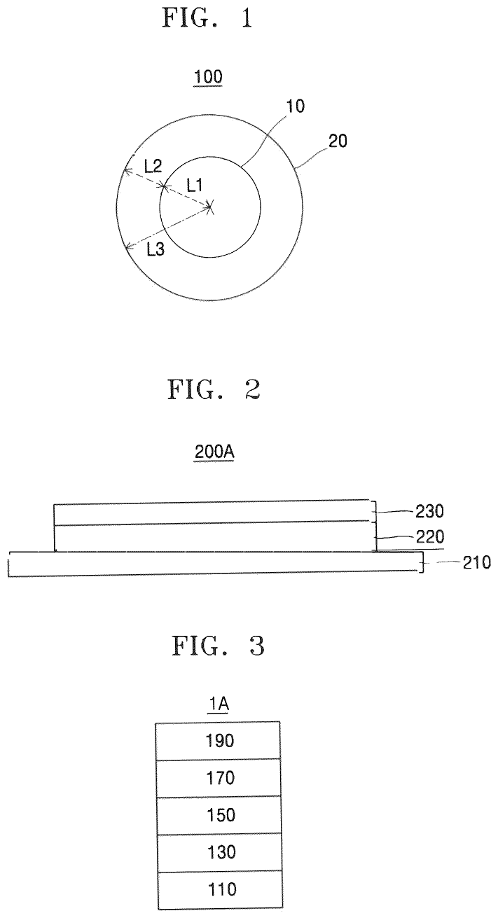

Hereinafter, a quantum dot 100 according to one or more embodiments and a method of preparing the quantum dot 100 will be described in connection with FIG. 1.

### Description of FIG. 1

FIG. 1 is a schematic cross-sectional view of a quantum dot 100 according to one or more embodiments. The quantum dot 100 may include a core 10 and a first shell 20.

### Quantum Dot 100

The quantum dot 100 in FIG. 1 may include: the core 10 including indium (In) and A¹; and
the first shell 20 covering the core 10,
wherein A¹ may be a group III element other than indium,
a ratio of a radius L1 of the core 10 to a thickness L2 of the first shell may be in a range of about 3:1 to about 9:1, and
the quantum dot may emit blue light having a maximum emission wavelength in a range of about 440 nanometers (nm) to about 480 nm.

The “radius L1 of the core” used herein refers to a distance from a center of a quantum dot to an interface between the core and the first shell.

The “thickness L2 of the first shell” used herein refers to a distance from the interface between the core 10 and the first shell 20 to a surface (e.g., outer circumferential surface) of the first shell 20. For example, L2 may be equal to a value obtained by subtracting the radius L1 of the core from a distance L3 from the center of the quantum dot to the surface (e.g., outer circumferential surface) of the first shell.

As the quantum dot of the disclosure includes a core and a first shell, and a ratio of the radius L1 of the core 10 to the thickness L2 of the first shell is in a range of about 3:1 to about 9:1, surface defects on the surface of the core may be effectively (or suitably) suppressed or reduced, such that the quantum dot may have excellent or improved luminescence efficiency and blue light-emitting characteristics of a narrow half-width while maintaining suitable stability. Therefore, a high-quality optical member and an electronic apparatus having high colorimetric purity by using the quantum dot may be provided.

In one or more embodiments, the core may further include A² and B¹, and

A² may be a group I element, and B¹ may be a group VI element.

In one or more embodiments, A¹ may be Al, Ga, Tl, or any combination thereof.

In one or more embodiments, A² may be Ag, Cu, or any combination thereof.

In one or more embodiments, B¹ may be O, S, Se, Te, or any combination thereof.

In one or more embodiments, A¹ may be Ga or Al, A² may be Ag or Cu, and B¹ may be S or Se, and for example, A¹ may be Ga, A² may be Ag, and B¹ may be S.

However, embodiments are not limited thereto.

In one or more embodiments, the core may include a quaternary compound.

The “quaternary compound” refers to a compound containing four different types (or kinds) of elements.

In one or more embodiments, a content of indium in the core 10 may be greater than about 0 parts by mass and about 30 parts by mass or less, based on 100 parts by mass of indium and A¹ in the core 10. For example, a content of indium may be greater than about 0 parts by mass and about 30 parts by mass or less, greater than about 0 parts by mass and about 25 parts by mass or less, greater than about 0 parts by mass and about 10 parts by mass or less, but embodiments are not limited thereto.

The quantum dot according to one or more embodiments may emit blue light with high colorimetric purity by satisfying a set or certain range of the molar ratio of gallium to indium in the core.

In one or more embodiments, the core 10 may include a group I-III-VI semiconductor compound.

In one or more embodiments, the core 10 may include a first semiconductor compound represented by Formula 1:

A²In_{xA}¹₁₋ₓB¹₂, Formula 1
wherein, in Formula 1,
A¹ may be a group III element other than indium,
A² may be a group I element,
B¹ may be a group VI element, and
x may be greater than 0 and smaller than 1.

In one or more embodiments, the first shell may include A³ and B²,
A³ may be a group III element, and
B² may be a group VI element.

In one or more embodiments, A³ may be Al, Ga, In, Tl, or any combination thereof.

In one or more embodiments, B² may be O, S, Se, Te, or any combination thereof.

For example, A³ may be Ga, and B² may be S.

In one or more embodiments, A¹ and A³ may be identical to each other.

In one or more embodiments, the first shell may include a group III-VI semiconductor compound.

Examples of the group III-VI semiconductor compound may include a binary compound such as GaS_{y}, GaSe_{y}, GaTe_{y}, AlS_{y}, AlSe_{y}, AlTe_{y}, InS_{y}, InSe_{y}, and/or InTe_{y}; a ternary compound such as GaSeS, GaSeTe, GaSTe, AlSeS, AlSeTe, AlSTe, InSeS, InSeTe, and/or InSTe; a quaternary compound such as GaAlSeS, GaAlSeTe, GaAlSTe, GaInSeS, GaInSeTe, GaInSTe, AlInSeS, AlInSeTe, and/or AlInSTe; and any combination thereof.

In one or more embodiments, the first shell 20 may include a second semiconductor compound represented by Formula 2:

A³B²_{y}, Formula 2
wherein, in Formula 2,
A³ may be a group III element,
B² may be a group VI element, and
y may be an integer of 0.5 or greater and 2 or lower.

In one or more embodiments, a radius of the core 10 may be about 3 nm or greater and about 10 nm or less.

In one or more embodiments, a thickness L2 of the first shell 20 may be greater than about 0.5 nm and about 4 nm or less.

In one or more embodiments, A¹ may be present in a substantially uniform or substantially ununiform concentration in the core 10.

In one or more embodiments, A² may be present in a substantially uniform or substantially ununiform concentration in the core 10.

In one or more embodiments, B¹ may be present in a substantially uniform or substantially ununiform concentration in the core 10.

In one or more embodiments, A³ may be present in a substantially uniform or substantially ununiform concentration in the first shell 20.

In one or more embodiments, B² may be present in a substantially uniform or substantially ununiform concentration in the first shell 20.

In one or more embodiments, the quantum dot may further include a second shell covering the first shell 20.

As the quantum dot 100 according to one or more embodiments may further include the second shell, a quantum dot with a multi-shell structure may be synthesized, thereby preventing or reducing exciton leakage in the core 10 and improving stability and quantum efficiency of the quantum dot 100. In addition, in the optical member and electronic apparatus, the multi-shell structure may have the effect of suppressing or reducing the decrease in efficiency due to energy transfer caused by the close distance between the cores due to the thin shell thickness.

In one or more embodiments, the second shell may include A⁴ and B³, and
A⁴ may be a group II element, and B³ may be a group VI element.

In one or more embodiments, A⁴ may include Mg, Ca, Zn, Cd, Hg, or any combination thereof.

In one or more embodiments, B³ may be O, S, Se, Te, or any combination thereof.

For example, A⁴ may be Mg or Zn, and B³ may be S.

In one or more embodiments, the second shell may include a group I-VI semiconductor compound.

Examples of the group II-VI semiconductor compound may include a binary compound such as CdS, CdSe, CdTe, ZnS, ZnSe, ZnTe, ZnO, HgS, HgSe, HgTe, MgSe, and/or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound such as CdZnSeS, CdZnSeTe, CdZnSTe, CdHgSeS, CdHgSeTe, CdHgSTe, HgZnSeS, HgZnSeTe, and/or HgZnSTe; and any combination thereof.

In one or more embodiments, the second shell may include a third semiconductor compound represented by Formula 3:

A⁴B³, Formula 3
wherein, in Formula 3,
A⁴ may be a group II element, and
B³ may be a group VI element.

According to one or more embodiments, a ratio of the thickness L2 of the first shell to a thickness of the second shell may be in a range of about 1:1 to about 10:1 or about 1:1 to about 6:1.

The “thickness of the second shell” used herein refers to a distance from the interface between the first shell and the second shell to a surface (e.g., outer circumferential surface) of the second shell. For example, the thickness may be equal to a value obtained by subtracting the distance from the center of the quantum dot to the interface between the first shell and the second shell from the distance from the center of the quantum dot to a surface (e.g., outer circumferential surface) of the second shell.

In one or more embodiments, the thickness of the second shell may be in a range of about 0.1 nm to about 1.0 nm.

In one or more embodiments, A⁴ may be present in a substantially uniform or substantially ununiform concentration in the second shell.

In one or more embodiments, B³ may be present in a substantially uniform or substantially ununiform concentration in the second shell.

In one or more embodiments, the quantum dot 100 may be, for example, a spherical, pyramidal, multi-arm, and/or cubic nanoparticle, nanotube, nanowire, nanofiber, and/or nanoplate particle.

In one or more embodiments, the quantum dot 100 may be spherical.

In one or more embodiments, an average radius of the quantum dot 100 may be about 3 nm or greater and about 15 nm or less.

In one or more embodiments, a maximum emission wavelength in the PL spectrum of the quantum dot 100 may be in a range of about 440 nm to about 480 nm, about 445 nm to about 480 nm, about 440 nm to about 475 nm, or about 445 nm to about 475 nm.

In one or more embodiments, a photoluminescence efficiency of the quantum dot 100 may be about 35% or greater and 95% or less, 37% or greater and 95% or less, or 40% or greater and 95% or less.

In one or more embodiments, the quantum dot 100 may have a full width of half maximum (FWHM) of a spectrum of an emission wavelength of about 40 nm or less, about 38 nm or less, or about 35 nm or less. When the FWHM of the quantum dot 100 is within any of these ranges, colorimetric purity and/or color reproducibility may be improved. In addition, because light emitted through the quantum dots is emitted in all directions, an optical viewing angle may be improved.

In one or more embodiments, the quantum dot 100 may be prepared by the method of preparing the quantum dot as described herein.

The quantum dot 100 may be synthesized by a wet chemical process, an organic metal chemical vapor deposition process, a molecular beam epitaxy process, or any similar suitable process.

The wet chemical process is a method of growing a quantum dot particle crystal by mixing a precursor material with an organic solvent. When the crystal grows, the organic solvent may naturally serve as a dispersant coordinated on the surface of the quantum dot crystal and control the growth of the crystal. Thus, the wet chemical method may be easier to perform than the vapor deposition process such a metal organic chemical vapor deposition (MOCVD) and/or a molecular beam epitaxy (MBE) process. Further, the growth of quantum dot particles may be controlled with a lower manufacturing cost.

The quantum dot 100 may include a group II-VI semiconductor compound; a group III-V semiconductor compound; a group III-VI semiconductor compound; a group I-III-VI semiconductor compound; a group IV-VI semiconductor compound; a group IV element, a group IV compound; or any combination thereof.

Examples of the group II-VI semiconductor compound may include a binary compound such as CdS, CdSe, CdTe, ZnS, ZnSe, ZnTe, ZnO, HgS, HgSe, HgTe, MgSe, and/or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS; a quaternary compound such as CdZnSeS, CdZnSeTe, CdZnSTe, CdHgSeS, CdHgSeTe, CdHgSTe, HgZnSeS, HgZnSeTe, and/or HgZnSTe; and any combination thereof.

Examples of the group III-V semiconductor compound may include a binary compound such as GaN, GaP, GaAs, GaSb, AlN, AlP, AlAs, AlSb, InN, InP, InAs, and/or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb; and any combination thereof. In some embodiments, the group III-V semiconductor compound may further include a group II element. Examples of the group III-V semiconductor compound further including the group II element may include InZnP, InGaZnP, InAlZnP, and the like.

Examples of the III-VI group semiconductor compound may include a binary compound such as GaS, GaSe, Ga₂Se₃, GaTe, InS, InSe, In₂S₃, In₂Se₃, InTe, and/or the like; a ternary compound such as InGaS₃, InGaSe₃, and/or the like; and any combination thereof.

Examples of the group I-III-VI semiconductor compound may include a ternary compound such as AgGaS₂, AgGaSe₂, AgInS, AgInS₂, CuInS, CuInS₂, CuGaO₂, AgGaO₂, and/or AgAlO₂; and any combination thereof.

Examples of the group IV-VI semiconductor compound may include a binary compound such as SnS, SnSe, SnTe, PbS, PbSe, and/or PbTe; a ternary compound such as SnSeS, SnSeTe, SnSTe, PbSeS, PbSeTe, PbSTe, SnPbS, SnPbSe, and/or SnPbTe; a quaternary compound such as SnPbSSe, SnPbSeTe, and/or SnPbSTe; and any combination thereof.

The group IV element and the group IV compound may be a single element material such as Si and/or Ge; a binary compound such as SiC and/or SiGe; or any combination thereof.

Individual elements included in the multi-element compound, such as a binary compound, a ternary compound, and/or a quaternary compound, may be present in a particle thereof at a substantially uniform or substantially non-uniform concentration.

The shell 20 of the quantum dot may serve as a protective layer for preventing or reducing chemical denaturation of the core 10 to maintain semiconductor characteristics and/or as a blocking layer that may form a band offset. The shell 20 may be a monolayer or a multilayer. An interface between a core and a shell may have a concentration gradient where a concentration of elements present in the shell decreases toward the core.

Examples of the shell 20 of the quantum dot may further include metal oxide, metalloid oxide, and/or nonmetal oxide, a semiconductor compound, or a combination thereof. Examples of the metal oxide, the metalloid oxide, and the nonmetal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO; a ternary compound such as MgAl₂O₄, CoFe₂O₄, NiFe₂O₄, and/or CoMn₂O₄; and any combination thereof. Examples of the semiconductor compound may include a group II-VI semiconductor compound; a group III-V semiconductor compound; a group III-VI semiconductor compound; a group I-III-VI semiconductor compound; a group IV-VI semiconductor compound; and any combination thereof. In some embodiments, the semiconductor compound may be CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

By adjusting the size of the quantum dot 100, the energy band gap may also be adjusted, thereby obtaining light of various wavelengths in the quantum dot emission layer. By using quantum dots of various sizes, a light-emitting device that may emit light of various wavelengths may be realized. In some embodiments, the size of the quantum dot may be selected such that the quantum dot may emit red, green, and/or blue light. In addition, the size of the quantum dot may be selected such that the quantum dot may emit white light by combining various light colors.

### Method of Manufacturing Quantum Dot

The method of preparing the quantum dot 100 may include: mixing a first precursor including indium (In) with a second precursor including A¹ to prepare a core; and
mixing a third precursor including A³ with a fourth precursor including B² to prepare a first shell,
wherein A¹ may be a group III element other than indium, A³ may be a group Ill element, and B² may be a group VI element.
a molar ratio of the second precursor to the third precursor may be about 1:5.2 or greater.

For example, a weight ratio of the second precursor to the third precursor may be about 1:5.2 or greater and about 1:12 or less, about 1:5.2 or greater and about 1:12 or less, about 1:5.5 or greater and about 1:11 or less, about 1:5.5 or greater and about 1:10.5 or less, or about 1:5.2 or greater and about 1:11 or less, but embodiments are not limited thereto.

A¹, A³, and B² may respectively be understood by referring to the descriptions of A¹, A³, and B² provided herein.

When the method of preparing the quantum dot according to one or more embodiments satisfies the molar ratio of the second precursor to the third precursor, the thus prepared quantum dot may have a suitable ratio of the radius of the core to the thickness of the first shell, thus having a high luminescence efficiency and low FWHM.

In one or more embodiments, a content of indium in the first precursor may be greater than about 0 parts by mass and about 30 parts by mass or less, based on 100 parts by mass of indium in the first precursor and A¹ in the second precursor.

In one or more embodiments, the preparing of the core may further include, after mixing the first precursor including indium (In) with the second precursor including A¹, heat-treating, wherein the heat-treating may be performed at a temperature of about 270° C. or greater and about 320° C. or less.

For example, the heat-treating may be performed at about 270° C. or greater and about 320° C. or less, about 280° C. or greater and about 320° C. or less, or about 285° C. or greater and about 320° C. or less, but embodiments are not limited thereto.

In one or more embodiments, the first precursor and the second precursor may be mixed together with a seventh precursor including A² and an eighth precursor including B¹ to prepare a core, and A² and B¹ may respectively be understood by referring to the descriptions of A² and B¹ provided herein.

In one or more embodiments, the method may further include purifying after the preparing of the core, and forming the first shell after the purifying.

By effectively or suitably removing precursors and/or unreacted substances that do not participate in a reaction through the purifying, the quantum dot of the disclosure may form a more uniform shell.

In one or more embodiments, the method may further include, after the forming of the first shell, mixing a fifth precursor including A⁴ with a sixth precursor including B³ to form a second shell, wherein A⁴ may be a group II element, and B³ may be a group VI element.

A⁴ and B³ may respectively be understood by referring to the descriptions of A⁴ and B³ provided herein.

The first precursor, the second precursor, the third precursor, the fifth precursor, and the seventh precursor may each independently be in a metal form, organic acid salt form, halogen salt form, carbonate form, nitric salt form, nitrate form, oxide form, sulfide form, acetate salt, or any combination thereof, but embodiments are not limited thereto.

The fourth precursor, the sixth precursor, and the eighth precursor may each independently be tributylphosphine-sulfide (TBP-S), trioctylphosphine-sulfide (TOP-S), oleic acid-sulfide (S-(oleic acid)), octadecene-sulfide (S-(1-octadecene)), oleylamine-sulfide (S-(oleylamine)), dodecanthiol-sulfide (S-(1-dodecanethiol)), or any combination thereof, but embodiments are not limited thereto.

### Optical Member

The quantum dot may be used in one or more suitable optical members. According to one or more embodiments, provided is an optical member including the quantum dot.

In one or more embodiments, the optical member may be alight controller.

In one or more embodiments, the optical member may be a color filter, a color conversion member, a capping layer, a light-extraction efficiency enhancement layer, a selective light-absorption layer, and/or a polarizing layer.

### Apparatus

The quantum dot may be used in one or more suitable electronic apparatuses. According to one or more embodiments, provided is an electronic apparatus including the quantum dot.

According to one or more embodiments, provided is an electronic apparatus including: a light source; and a color conversion member located on a pathway of light emitted from the light source, wherein the color conversion member may include the quantum dot.

FIG. 2 is a schematic view showing a structure of an electronic apparatus 200A according to one or more embodiments. The electronic apparatus 200A of FIG. 2 may include a substrate 210, a light source arranged on the substrate 210, and a color conversion member 230 arranged on the light source 220.

For example, the light source 220 may be a backlight unit (BLU) for use in liquid crystal displays (LCD), a fluorescent lamp, a light-emitting device, an organic light-emitting device, a quantum-dot light-emitting device (QLED), or any combination thereof. The color conversion member 230 may be arranged in at least one traveling direction of light emitted from the light source 220.

At least part of the color conversion member 230 in the electronic apparatus 200A may include the quantum dot, and the region may absorb light emitted from the light source to thereby emit blue light having a maximum emission wavelength in a range of about 440 nm to about 480 nm.

That the color conversion member 230 is arranged in at least one traveling direction of light emitted from the light source 220 may not exclude other elements from being further included between the color conversion member 230 and the light source 220 (e.g., may include other elements).

For example, between the light source 220 and the color conversion member 230, a polarizing plate, a liquid crystal layer, a light guide plate, a diffusion plate, a prism sheet, a microlens sheet, a luminance enhancing sheet, a reflective film, a color filter, or any combination thereof may be additionally arranged.

In some embodiments, a polarizing plate, a liquid crystal layer, a light guide plate, a diffusion plate, a prism sheet, a microlens sheet, a luminance enhancing sheet, a reflective film, a color filter, or any combination thereof may be additionally arranged on the color conversion member 230.

The electronic apparatus 200A illustrated in FIG. 2, which is according to one or more embodiments of the disclosure, may have any suitable shape, and accordingly, may further include one or more suitable structures.

In some embodiments, the electronic apparatus may include a structure including a light source, a light guide plate, a color conversion member, a first polarizing plate, a liquid crystal layer, a color filter, and a second polarizing plate that are sequentially arranged.

In some embodiments, the electronic apparatus may include a structure including a light source, a light guide plate, a first polarizing plate, a liquid crystal layer, a second polarizing plate, and a color conversion member that are sequentially arranged.

In the embodiments described above, the color filter may include a pigment and/or a dye. In the embodiments described above, one of the first polarizing plate and/or the second polarizing plate may be a vertical polarizing plate, and the other one may be a horizontal polarizing plate.

In some embodiments, the quantum dot as described in the present specification may be used as an emitter. According to one or more embodiments, provided is an electronic apparatus including a light-emitting device that may include: a first electrode; a second electrode facing the first electrode; and an emission layer located between the first electrode and the second electrode, wherein the light-emitting device (for example, the emission layer of the light-emitting device) may include the quantum dot. The light-emitting device may further include a hole transport region between the first electrode and the emission layer, an electron transport region between the emission layer and the second electrode, or a combination thereof.

FIG. 3 is a schematic cross-sectional view showing a structure of a light-emitting device 1A according to one or more embodiments.

The light-emitting device 10A includes: a first electrode 110; a second electrode 190 facing the first electrode 110; an emission layer 150 located between the first electrode 110 and the second electrode 190 and including the quantum dot; a hole transport region 130 located between the first electrode 110 and the emission layer 150; and an electron transport region 170 located between the emission layer 150 and the second electrode 190. Hereinafter, the layers of the light-emitting device 10A will be described.

### First Electrode 110

In FIG. 3, a substrate may be additionally located under the first electrode 110 or above the second electrode 190. The substrate may be a glass substrate and/or a plastic substrate, each having excellent mechanical strength, thermal stability, transparency, surface smoothness, ease of handling, and/or water resistance.

For example, when the light-emitting device 10A is a top-emission type (or kind) in which light is emitted in the opposite direction of the substrate, the substrate may not be essentially (e.g., substantially) transparent, and may be opaque or semi-transparent. In this embodiment, the substrate may be formed of metal. When the substrate is formed of metal, the substrate may include carbon, iron, chromium, manganese, nickel, titanium, molybdenum, stainless steel (SUS), an Invar alloy, an Inconel alloy, a Kovar alloy, or any combination thereof.

In some embodiments, a buffer layer, a thin-film transistor, an organic insulating layer, and/or the like may be further included between the substrate and the first electrode 110.

The first electrode 110 may be formed by depositing or sputtering, onto the substrate, a material for forming the first electrode 110. The first electrode 110 may be a reflective electrode, a semi-transmissive electrode, or a transmissive electrode. To form the first electrode 110 which is a transmission-type (or kind) electrode, the material for the first electrode may include indium tin oxide (ITO), indium zinc oxide (IZO), tin oxide (SnO2), zinc oxide (ZnO), gallium zinc oxide (GZO), aluminum zinc oxide (AZO), InZnSnOx (IZSO), ZnSnOx (ZSO), graphene, PEDOT:PSS, carbon nanotubes, silver (Ag) nanowire, gold (Au) nanowire, metal mesh, or any combination thereof. In some embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a single-layered structure, or a multi-layered structure including two or more layers. In some embodiments, the first electrode 110 may have a triple-layered structure of ITO/Ag/ITO.

### Hole Transport Region 130

The hole transport region 130 may have i) a single-layered structure including (e.g., consisting of) a single layer including (e.g., consisting of) a single material, ii) a single-layered structure including (e.g., consisting of) a single layer including a plurality of different materials, or iii) a multi-layered structure having a plurality of layers including a plurality of different materials.

The hole transport region 130 may include a hole injection layer, a hole transport layer, an emission auxiliary layer, an electron blocking layer, or any combination thereof.

For example, the hole transport region 130 may have a single-layered structure including a single layer including a plurality of different materials or a multi-layered structure, e.g., a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein layers of each structure are sequentially stacked on the first electrode 110 in each stated order, but embodiments are not limited thereto.

The hole transport region 130 may include an amorphous inorganic material and/or organic material. The inorganic material may include NiO, MoO₃, Cr₂O₃, and/or Bi₂O₃ The inorganic material may include a p-type (e.g., P) inorganic semiconductor, for example, a p-type inorganic semiconductor in which an iodide, bromide, and/or chloride of Cu, Ag and/or Au is doped with non-metal such as O, S, Se and/or Te; a p-type inorganic semiconductor in which a Zn-containing compound is doped with metal, such as Cu, Ag and/or Au, and/or non-metal, such as N, P, As, Sb and/or Bi; and/or a spontaneous p-type inorganic semiconductor such as ZnTe.

The organic material may include m-MTDATA, TDATA, 2-TNATA, NPB (NPD), β-NPB, TPD, Spiro-TPD, Spiro-NPB, methylated-NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate (PANI/PSS), polyvinylcarbazole (PVK), a compound represented by Formula 201, a compound represented by Formula 202, or any combination thereof:

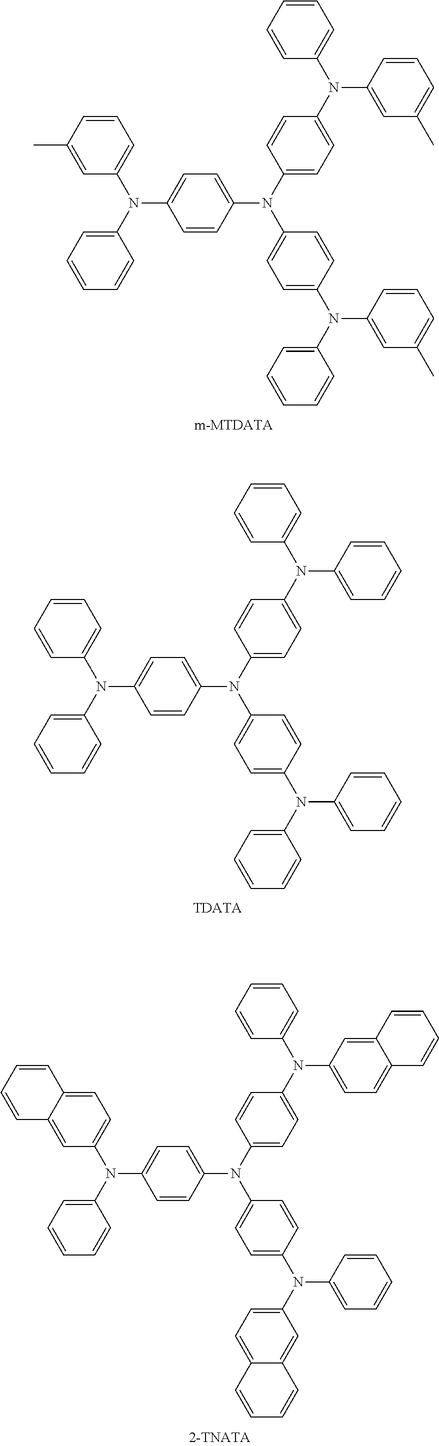

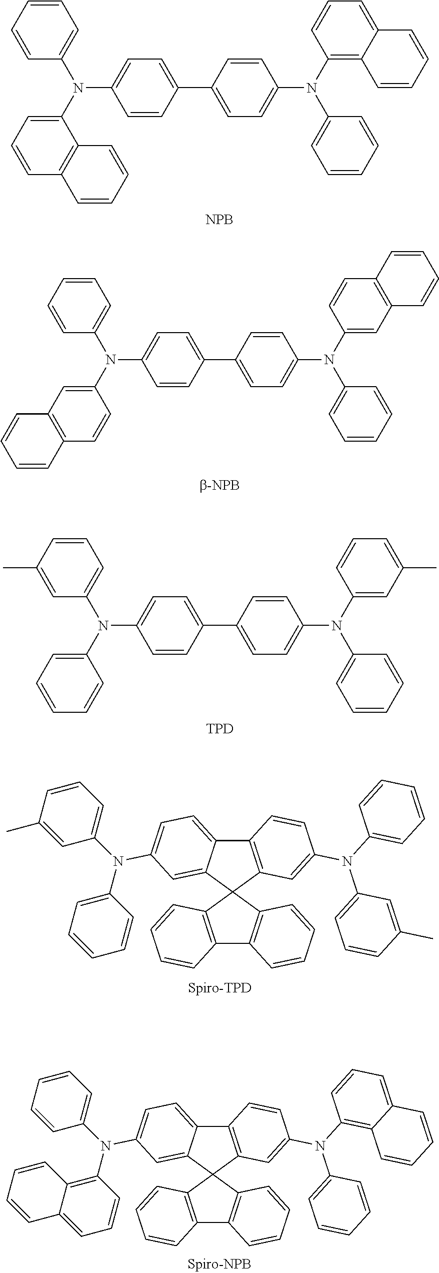

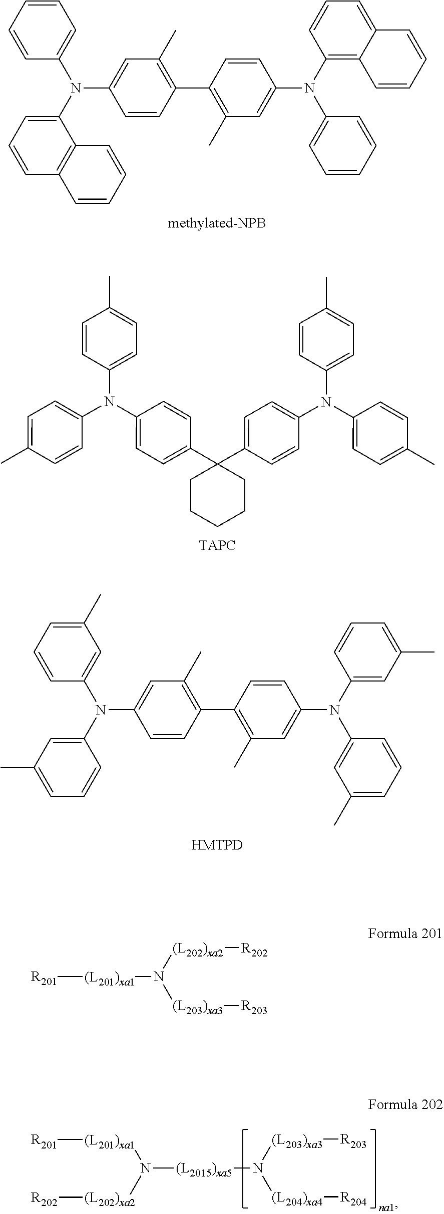

wherein, in Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be bound to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₈-C₆₀ polycyclic group (e.g., a carbazole group and/or the like) unsubstituted or substituted with at least one R₁₀ₐ,
R₂₀₃ and R₂₀₄ may optionally be bound to each other via a single bond, a C₁-C₅ alkylene group unsubstituted or substituted with at least one R₁₀ₐ or a C₂-C₅ alkenylene group unsubstituted or substituted with at least one R₁₀ₐ to form a C₈-C₆₀ polycyclic group unsubstituted or substituted with at least one R₁₀ₐ, and

na1 may be an integer from 1 to 4.

The thickness of the hole transport region 130 may be in a range of about 50 (Angstroms) Å to about 10,000 Å, and in some embodiments, about 100 Å to about 4,000 Å. When the hole transport region 130 includes a hole injection layer, a hole transport layer, or any combination thereof, the thickness of the hole injection layer may be in a range of about 100 Å to about 9,000 Å, and in some embodiments, about 100 Å to about 1,000 Å, and the thickness of the hole transport layer may be in a range of about 50 Å to about 2,000 Å, and in some embodiments, about 100 Å to about 1,500 Å. When the thicknesses of the hole transport region 130, the hole injection layer, and the hole transport layer are each independently within any of these ranges, excellent or improved hole transport characteristics may be obtained without a substantial increase in driving voltage.

The emission auxiliary layer may increase light emission efficiency by compensating for an optical resonance distance according to the wavelength of light emitted by an emission layer. The electron blocking layer may prevent or reduce leakage of electrons to a hole transport region 130 from the emission layer. Materials that may be included in the hole transport region 130 may also be included in an emission auxiliary layer and an electron blocking layer.

p-dopant

The hole transport region 130 may include a charge generating material as well as the aforementioned materials, to improve conductive properties of the hole transport region. The charge generating material may be substantially homogeneously or non-substantially homogeneously dispersed (for example, as a single layer including (e.g., consisting of) charge generating material) in the hole transport region 130.

The charge generating material may include, for example, a p-dopant.

In some embodiments, a lowest unoccupied molecular orbital (LUMO) energy level of the p-dopant may be −3.5 eV or less.

In some embodiments, the p-dopant may include a quinone derivative, a compound containing a cyano group, a compound containing element EL1 and element EL2, or any combination thereof.

Examples of the quinone derivative may include TCNQ, F4-TCNQ, and the like.

Examples of the compound containing a cyano group may include HAT-CN, a compound represented by Formula 221, and the like:

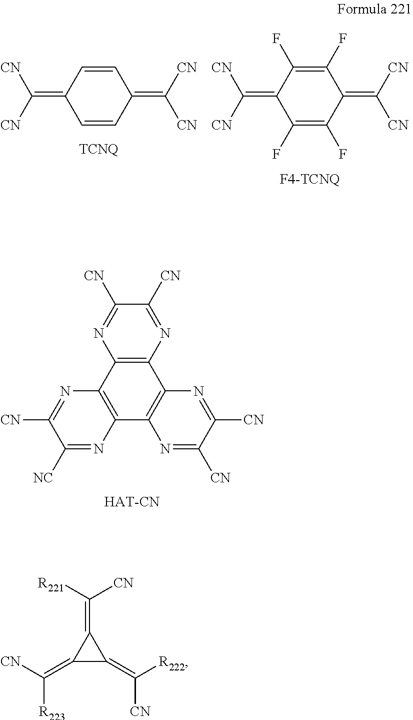

wherein, in Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
at least one of R₂₂₁ to R₂₂₃ may each independently be: a C₃-C₆₀ carbocyclic group or a C₁-C₆₀ heterocyclic group, substituted with a cyano group; —F; —Cl; —Br; —I; a C₁-C₂₀ alkyl group substituted with a cyano group, —F, —Cl, —Br, —I, or any combination thereof; or any combination thereof.

In the compound containing element EL1 and element EL2, element EL1 may be a metal, a metalloid, or a combination thereof, and element EL2 may be non-metal, a metalloid, or a combination thereof.

Examples of the metal may include: an alkali metal (e.g., lithium (Li), sodium (Na), potassium (K), rubidium (Rb), cesium (Cs), and/or the like); an alkaline earth metal (e.g., beryllium (Be), magnesium (Mg), calcium (Ca), strontium (Sr), barium (Ba), and/or the like); a transition metal (e.g., titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); post-transition metal (e.g., zinc (Zn), indium (In), tin (Sn), and/or the like); a lanthanide metal (e.g., lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like); and the like.

Examples of the metalloid may include silicon (Si), antimony (Sb), tellurium (Te), and the like.

Examples of the non-metal may include oxygen (O), halogen (e.g., F, Cl, Br, I, and/or the like), and the like.

For example, the compound containing element EL1 and element EL2 may include a metal oxide, a metal halide (e.g., metal fluoride, metal chloride, metal bromide, metal iodide, and/or the like), a metalloid halide (e.g., a metalloid fluoride, a metalloid chloride, a metalloid bromide, a metalloid iodide, and/or the like), a metal telluride, or any combination thereof.

Examples of the metal oxide may include a tungsten oxide (e.g., WO, W₂O₃, WO₂, WO₃, and/or W₂O₅), a vanadium oxide (e.g., VO, V₂O₃, VO₂, and/or V₂O₅), a molybdenum oxide (MoO, Mo₂O₃, MoO₂, MoO₃, and/or Mo₂O₅), and a rhenium oxide (e.g., ReO₃).

Examples of the metal halide may include alkali metal halide, alkaline earth metal halide, transition metal halide, post-transition metal halide, lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include a titanium halide (e.g., TiF₄, TiCl₄, TiBr₄, and/or TiI₄), a zirconium halide (e.g., ZrF₄, ZrCl₄, ZrBr₄, and/or ZrI₄), a hafnium halide (e.g., HfF₄, HfCl₄, HfBr₄, and/or HfI₄), a vanadium halide (e.g., VF₃, VCl₃, VBr₃, and/or VI₃), a niobium halide (e.g., NbF₃, NbCl₃, NbBr₃, and/or NbI₃), a tantalum halide (e.g., TaF₃, TaCl₃, TaBr₃, and/or TaI₃), a chromium halide (e.g., CrF₃, CrO₃, CrBr₃, and/or CrI₃), a molybdenum halide (e.g., MoF₃, MoCl₃, MoBr₃, and/or MoI₃), a tungsten halide (e.g., WF₃, WCl₃, WBr₃, and/or WI₃), a manganese halide (e.g., MnF₂, MnCl₂, MnBr₂, and/or MnI₂), a technetium halide (e.g., TcF₂, TcCl₂, TcBr₂, and/or TcI₂), a rhenium halide (e.g., ReF₂, ReCl₂, ReBr₂, and/or ReI₂), an iron halide (e.g., FeF₂, FeCl₂, FeBr₂, and/or FeI₂), a ruthenium halide (e.g., RuF₂, RuCl₂, RuBr₂, and/or RuI₂), an osmium halide (e.g., OsF₂, OsCl₂, OsBr₂, and/or OsI₂), a cobalt halide (e.g., CoF₂, COCl₂, CoBr₂, and/or CoI₂), a rhodium halide (e.g., RhF₂, RhCl₂, RhBr₂, and/or RhI₂), an iridium halide (e.g., IrF₂, IrCl₂, IrBr₂, and/or IrI₂), a nickel halide (e.g., NiF₂, NiCl₂, NiBr₂, and/or NiI₂), a palladium halide (e.g., PdF₂, PdCl₂, PdBr₂, and/or PdI₂), a platinum halide (e.g., PtF₂, PtCl₂, PtBr₂, and/or PtI₂), a copper halide (e.g., CuF, CuCl, CuBr, and/or CuI), a silver halide (e.g., AgF, AgCl, AgBr, and/or AgI), and a gold halide (e.g., AuF, AuCl, AuBr, and/or AuI).

Examples of the post-transition metal halide may include a zinc halide (e.g., ZnF₂, ZnCl₂, ZnBr₂, and/or ZnI₂), an indium halide (e.g., InI₃), and a tin halide (e.g., SnI₂).

Examples of the lanthanide metal halide may include YbF, YbF₂, YbF₃, SmF₃, YbCl, YbCl₂, YbCl₃ SmCl₃, YbBr, YbBr₂, YbBr₃, SmBr₃, YbI, YbI₂, YbI₃, and SmI₃.

Examples of the metalloid halide may include an antimony halide (e.g., SbCl₅).

Examples of the metal telluride may include an alkali metal telluride (e.g., Li₂Te, Na₂Te, K₂Te, Rb₂Te, and/or Cs₂Te), an alkaline earth metal telluride (e.g., BeTe, MgTe, CaTe, SrTe, and/or BaTe), a transition metal telluride (e.g., TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), a post-transition metal telluride (e.g., ZnTe), and a lanthanide metal telluride (e.g., LaTe, CeTe, PrTe, NdTe, PmTe, EuTe, GdTe, TbTe, DyTe, HoTe, ErTe, TmTe, YbTe, and/or LuTe).

Emission Layer 150

The emission layer 150 may be a quantum dot single layer or a laminate structure of at least two quantum dot layers. In some embodiments, the emission layer 150 may be a quantum dot single layer or a laminate structure of 2 to 100 quantum dot layers.

In some embodiments, the emission layer 150 may include quantum dot(s) described herein.

The emission layer 150, in addition to the quantum dot as described herein, may further include a dispersion medium in which the quantum dot is naturally dispersed in a coordinated form. The dispersion medium may include an organic solvent, a polymer resin, or any combination thereof. Any suitable transparent medium may be used as long as the dispersion medium may not affect (e.g., may not substantially affect) optical performance of the quantum dot, may not change or reflect (e.g., may not substantially change or reflect) light, and may not cause (e.g., may not substantially cause) light absorption. For example, the solvent may include toluene, chloroform, ethanol, octane, or any combination thereof, and the polymer resin may include epoxy resin, silicone resin, polystyrene resin, acrylate resin, or any combination thereof.

The emission layer 150 may be formed by applying a composition for forming an emission layer including quantum dots on the hole transport region 130 and volatilizing at least some of the solvent included in the composition for forming the emission layer.

For example, as the solvent, water, hexane, chloroform, toluene, octane, and/or the like may be used.

The coating of the composition for forming the emission layer may be performed using a spin coat method, a casting method, a micro gravure coating method, a gravure coating method, a bar coating method, a roll coating method, a wire bar coating method, a dip coating method, a spray coating method, a screen printing method, a flexographic method, an offset printing method, an ink jet printing method, and/or the like.

When the light-emitting device 10A is a full-color light-emitting device, in the emission layer 150, individual sub-pixels may include emission layers emitting (e.g., configured to emit) different colors.

In some embodiments, the emission layer 150 may be patterned into a first color emission layer, a second color emission layer, and a third color emission layer, according to a sub-pixel. In this embodiment, at least one emission layer among the foregoing emission layers may necessarily include the quantum dot. In some embodiments, the first color emission layer may be a quantum dot emission layer including a quantum dot, and the second color emission layer and the third color emission layer may be organic emission layers each including different organic compounds. In this embodiment, the first color to the third color may be different from one another, and in some embodiments, the first color to the third color may each have different maximum emission wavelengths. The first color to the third color may be combined to be white light.

In some embodiments, the emission layer 150 may further include a fourth color emission layer, at least one emission layer of the first color to the fourth color emission layers may be a quantum dot emission layer including a quantum dot, and the other emission layers may be organic emission layers each including organic compounds. Such a variation may be made. In this embodiment, the first color to the fourth color may be different from one another, and in some embodiments, the first color to the fourth color may each have different maximum emission wavelengths. The first color to the fourth color may be combined to be white light.

In some embodiments, the light-emitting device 10A may have a structure in which at least two emission layers, each emitting (e.g., configured to emit) the same color or different colors, may be in contact with or spaced apart from each other. At least one emission layer of the at least two emission layers may be a quantum dot emission layer including the quantum dot(s), and the other emission layer may be an organic emission layer including organic compounds. Such a variation may be made.

For example, the light-emitting device 10A may include a first color emission layer and a second color emission layer, wherein the first color and the second color may be the same color or different colors. For example, both the first color and the second color may be blue.

The emission layer 150 may further include at least one selected from organic compounds and semiconductor compounds, in addition to quantum dots.

In one or more embodiments, the organic compound may include a host and a dopant. The host and the dopant may be any suitable host and dopant to be used in organic light-emitting devices.

In some embodiments, the semiconductor compound may be an organic perovskite and/or an inorganic perovskite.

Electron Transport Region 170

The electron transport region may have i) a single-layered structure including (e.g., consisting of) a single layer including (e.g., consisting of) a single material, ii) a single-layered structure including (e.g., consisting of) a single layer including a plurality of different materials, or iii) a multi-layered structure having a plurality of layers including a plurality of different materials.

The electron transport region 170 may include at least one selected from a buffer layer, a hole blocking layer, an electron control layer, an electron transport layer, and/or an electron injection layer, but embodiments are not limited thereto.

In some embodiments, the electron transport region 170 may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein layers of each structure are sequentially stacked on the emission layer 150 in each stated order, but embodiments are not limited thereto.

The electron transport region 170 may include a conductive metal oxide. For example, the metal oxide may include ZnO, TiO₂, WO₃, SnO₂, In₂O₃, Nb₂O₅, Fe₂O₃, CeO₂, SrTiO₃, Zn₂SnO₄, BaSnO₃, In₂S₃, ZnSiO, PC60BM, PC70BM, Mg-doped ZnO (ZnMgO), Al-doped ZnO (AZO), Ga-doped ZnO (GZO), In-doped ZnO (IZO), Al-doped TiO₂, Ga-doped TiO₂, In-doped TiO₂, Al-doped WO₃, Ga-doped WO₃, In-doped WO₃, Al-doped SnO₂, Ga-doped SnO₂, In-doped SnO₂, Mg-doped In₂O₃, Al-doped In₂O₃, Ga-doped In₂O₃, Mg-doped Nb₂O₅, Al-doped Nb₂O₅, Ga-doped Nb₂O₅, Mg-doped Fe₂O₃, Al-doped Fe₂O₃, Ga-doped Fe₂O₃, In-doped Fe₂O₃, Mg-doped CeO₂, Al-doped CeO₂, Ga-doped CeO₂, In-doped CeO₂, Mg-doped SrTiO₃, Al-doped SrTiO₃, Ga-doped SrTiO₃, In-doped SrTiO₃, Mg-doped Zn₂SnO₄, Al-doped Zn₂SnO₄, Ga-doped Zn₂SnO₄, In-doped Zn₂SnO₄, Mg-doped BaSnO₃, Al-doped BaSnO₃, Ga-doped BaSnO₃, In-doped BaSnO₃, Mg-doped In₂S₃, Al-doped In₂S₃, Ga-doped In₂S₃, In-doped In₂S₃, Mg-doped ZnSiO, Al-doped ZnSiO, Ga-doped ZnSiO, In-doped ZnSiO, or any combination thereof.

In some embodiments, the organic material may include a compound having suitable electron transportability, such as 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), and/or NTAZ:

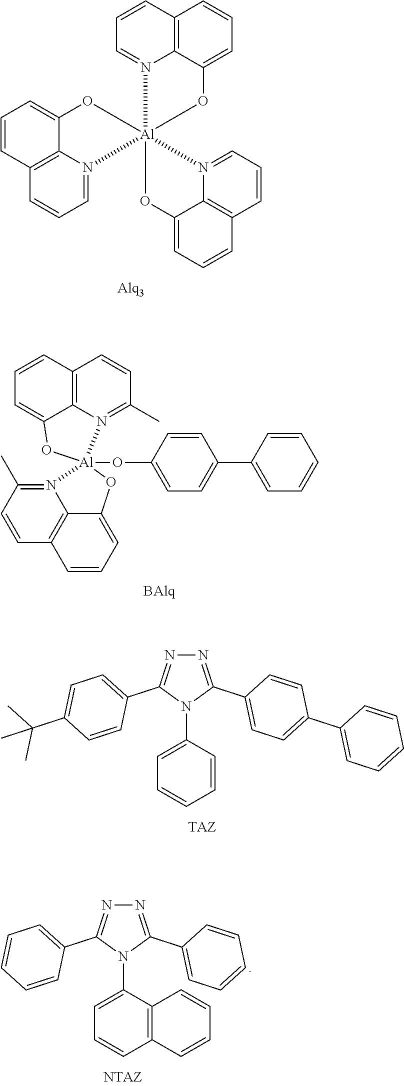

In one or more embodiments, the organic material may be a metal-free compound including at least one π electron-depleted nitrogen-containing C₁-C₆₀ cyclic group.

In some embodiments, the electron transport region 170 may include a compound represented by Formula 601:

[Ar₆₀₁]ₓₑ₁₁-[(L₆₀₁)ₓₑ₁-R₆₀₁]ₓₑ₂₁, Formula 601
wherein, in Formula 601,
Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
wherein Q₆₀₁ to Q₆₀₃ may each be understood by referring to the description of Q₁ provided herein,
xe21 may be 1, 2, 3, 4, or 5, and
at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

The thickness of the electron transport region 170 may be in a range of about 160 (Angstroms) Å to about 5,000 Å, and in some embodiments, about 100 Å to about 4,000 Å. When the electron transport region 170 includes a buffer layer, a hole blocking layer, an electron control layer, an electron transport layer, or any combination thereof, the thicknesses of the buffer layer, the hole blocking layer, and/or the electron control layer may each independently be in a range of about 20 Å to about 1,000 Å, for example, about 30 Å to about 300 Å, and the thickness of the electron transport layer may be in a range of about 100 Å to about 1,000 Å, for example, about 150 Å to about 500 Å. When the thicknesses of the buffer layer, the hole blocking layer, the electron control layer, the electron transport layer, and/or the electron transport layer are each independently within these ranges, excellent or improved electron transport characteristics may be obtained without a substantial increase in driving voltage.

The electron transport region 170 (e.g., the electron transport layer in the electron transport region 17) may further include, in addition to the materials described above, a material including metal.

The metal-containing material may include an alkali metal complex, an alkaline earth metal complex, or any combination thereof. A metal ion of the alkali metal complex may be a lithium (Li) ion, a sodium (Na) ion, a potassium (K) ion, a rubidium (Rb) ion, and/or a cesium (Cs) ion. A metal ion of the alkaline earth metal complex may be a beryllium (Be) ion, a magnesium (Mg) ion, a calcium (Ca) ion, a strontium (Sr) ion, and/or a barium (Ba) ion. A ligand coordinated with the metal ion of the alkali metal complex and/or the alkaline earth metal complex may each independently be hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

For example, the metal-containing material may include a Li complex. The Li complex may include, e.g., Compound ET-D1 (LiQ) and/or Compound ET-D2:

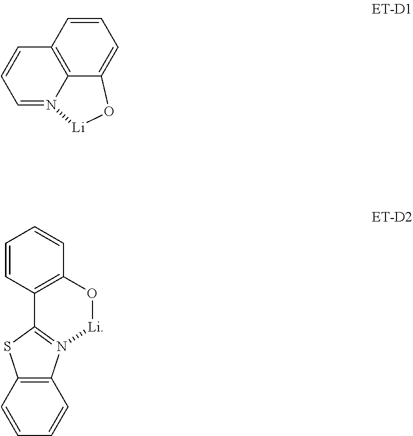

The electron transport region 170 may include an electron injection layer that facilitates injection of electrons from the second electrode 190. The electron injection layer may be in direct contact with the second electrode 190.

The electron injection layer may have i) a single-layered structure including (e.g., consisting of) a single layer including (e.g., consisting of) a single material, ii) a single-layered structure including (e.g., consisting of) a single layer including a plurality of different materials, or iii) a multi-layered structure having a plurality of layers including a plurality of different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may be Li, Na, K, Rb, Cs or any combination thereof. The alkaline earth metal may be Mg, Ca, Sr, Ba, or any combination thereof. The rare earth metal may be Sc, Y, Ce, Tb, Yb, Gd, or any combination thereof.

The alkali metal-containing compound, the alkaline earth metal-containing compound, and the rare earth metal-containing compound may be one or more oxides, halides (e.g., fluorides, chlorides, bromides, and/or iodides), tellurides, or any combination thereof of the alkali metal, the alkaline earth metal, and the rare earth metal.

The alkali metal-containing compound may include alkali metal oxides such as Li₂O, Cs₂O, and/or K₂O; alkali metal halides such as LiF, NaF, CsF, KF, LiI, NaI, CsI, and/or KI; or any combination thereof. The alkaline earth-metal-containing compound may include alkaline earth-metal oxides, such as BaO, SrO, CaO, BaₓSr₁₋ₓO (wherein x is a real number satisfying 0<x<1), and/or BaₓCa₁₋ₓO (wherein x is a real number satisfying 0<x<1). The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In some embodiments, the rare earth metal-containing compound may include a lanthanide metal telluride. Examples of the lanthanide metal telluride include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth metal complex, and the rare earth metal complex may include: i) one of ions of the alkali metal, alkaline earth metal, and rare earth metal described above, respectively and ii) a ligand bonded to the metal ion, e.g., hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenylbenzimidazole, hydroxyphenylbenzothiazole, bipyridine, phenanthroline, cyclopentadiene, or any combination thereof.

The electron injection layer may include (e.g., may consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In some embodiments, the electron injection layer may further include an organic material (e.g., a compound represented by Formula 601).

In some embodiments, the electron injection layer may include (e.g., may consist of) i) an alkali metal-containing compound (e.g., alkali metal halide), or ii) a) an alkali metal-containing compound (e.g., alkali metal halide); and b) an alkali metal, an alkaline earth metal, a rare earth metal, or any combination thereof. In some embodiments, the electron injection layer may be a KI:Yb co-deposition layer, a RbI:Yb co-deposition layer, a Li:F co-deposition layer, and/or the like.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth metal complex, the rare earth metal complex, or any combination thereof may be homogeneously or non-homogeneously dispersed in a matrix including the organic material.

The thickness of the electron injection layer may be in a range of about 1 Å to about 100 Å, and in some embodiments, about 3 Å to about 90 Å. When the thickness of the electron injection layer is within any of these ranges, excellent or improved electron injection characteristics may be obtained without a substantial increase in driving voltage.

### Second Electrode 190

The second electrode 190 may be on the electron transport region 170. In one or more embodiments, the second electrode 190 may be a cathode that is an electron injection electrode. In this embodiment, a material for forming the second electrode 190 may be a material having a low work function, for example, a metal, an alloy, an electrically conductive compound, or any combination thereof.

The second electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 190 may be a transmissive electrode, a semi-transmissive electrode, or a reflective electrode.

The second electrode 190 may have a single-layered structure, or a multi-layered structure including two or more layers.

The electronic apparatus (e.g., a light-emitting apparatus) may further include, in addition to the light-emitting device 10A, i) a color filter, ii) a color conversion layer, or iii) a color filter and a color conversion layer. The color filter and/or the color-conversion layer may be provided on at least one traveling direction of light emitted from the light-emitting device 10A. For example, light emitted from the light-emitting device 10A may be blue light or white light. The light-emitting device 10A may be understood by referring to the descriptions provided herein. In some embodiments, the color conversion layer may include quantum dots. The quantum dot may be, for example, the quantum dot described herein.

The electronic apparatus may further include a thin-film transistor, in addition to the light-emitting device 10A. The thin-film transistor may include a source electrode, a drain electrode, and an activation layer, wherein one of the source electrode or the drain electrode may be electrically connected to one of the first electrode 110 or the second electrode 190 of the light-emitting device 10A.

The thin-film transistor may further include a gate electrode, a gate insulating film, and/or the like.

The active layer may include a crystalline silicon, an amorphous silicon, an organic semiconductor, and/or an oxide semiconductor.

The electronic apparatus may further include an encapsulation unit for sealing the light-emitting device 10A. The encapsulation unit may be located between the light-emitting device 10A and the color filter and/or the color conversion layer. The encapsulation unit may allow light to pass to the outside from the light-emitting device 10A and prevent or reduce the penetration of the air and/or moisture into the light-emitting device 10A at the same time. The encapsulation unit may be a sealing substrate including transparent glass and/or a plastic substrate. The encapsulation unit may be a thin-film encapsulating layer including at least one of an organic layer and/or an inorganic layer. When the encapsulation unit is a thin-film encapsulating layer, the electronic apparatus may be flexible.

In addition to the color filter and/or the color conversion layer, one or more functional layers may be provided on the encapsulation unit depending on the use of an electronic apparatus. Examples of the functional layer may include a touch screen layer, a polarizing layer, and the like. The touch screen layer may be a resistive touch screen layer, a capacitive touch screen layer, and/or an infrared beam touch screen layer. The authentication apparatus may be, for example, a biometric authentication apparatus that identifies an individual according to biometric information (e.g., a fingertip, a pupil, and/or the like).

The authentication apparatus may further include a biometric information collecting unit, in addition to the light-emitting device 10A described above.

The electronic apparatus may be applicable to one or more suitable displays, an optical source, lighting, a personal computer (e.g., a mobile personal computer), a cellphone, a digital camera, an electronic note, an electronic dictionary, an electronic game console, a medical device (e.g., an electronic thermometer, a blood pressure meter, a glucometer, a pulse measuring device, a pulse wave measuring device, an electrocardiograph recorder, an ultrasonic diagnosis device, and/or an endoscope display device), a fish finder, various measurement devices, gauges (e.g., gauges of an automobile, an airplane, and/or a ship), and/or a projector.

### General Definitions of Terms

The term “C₃-C₆₀ carbocyclic group” as used herein refers to a cyclic group consisting of carbon atoms only as ring-forming atoms and having 3 to 60 carbon atoms as ring-forming atoms. The term “C₁-C₆₀ heterocyclic group” as used herein refers to a cyclic group having 1 to 60 carbon atoms in addition to at least one heteroatom as ring-forming atoms, other than carbon atoms. The C₃-C₆₀ carbocyclic group and the C₁-C₆₀ heterocyclic group may each independently be a monocyclic group consisting of one ring or a polycyclic group in which at least two rings are condensed. For example, the number of ring-forming atoms in the C₁-C₆₀ heterocyclic group may be in a range of 3 to 61.

The term “cyclic group” as used herein may include the C₃-C₆₀ carbocyclic group and the C₁-C₆₀ heterocyclic group.

The term “π electron-rich C₃-C₆₀ cyclic group” refers to a cyclic group having 3 to 60 carbon atoms and not including *—N═*′ as a ring-forming moiety. The term “π electron-deficient nitrogen-containing C₁-C₆₀ cyclic group” as used herein refers to a heterocyclic group having 1 to 60 carbon atoms and including *—N═*′ as a ring-forming moiety.

In some embodiments,
the C₃-C₆₀ carbocyclic group may be i) a T1 group or ii) a group in which at least two T1 groups are condensed (for example, the C₃-C₆₀ carbocyclic group may be a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a T2 group, ii) a group in which at least two T2 groups are condensed, or iii) a group in which at least one T2 group is condensed with at least one T1 group (for example, the C₁-C₆₀ heterocyclic group may be a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
the π electron-rich C₃-C₆₀ cyclic group may be i) a T1 group, ii) a condensed group in which at least two T1 groups are condensed, iii) a T3 group, iv) a condensed group in which at least two T3 groups are condensed, or v) a condensed group in which at least one T3 group is condensed with at least one T1 group (for example, the π electron-rich C₃-C₆₀ cyclic group may be a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonapthothiophene group, a benzonaphthosilole group, a benzofurodibenzofuran group, a benzofurodibenzothiophene group, a benzothienodibenzothiophene group, and/or the like), and
the π electron-deficient nitrogen-containing C₁-C₆₀ cyclic group may be i) a T4 group, ii) a group in which at least two T4 groups are condensed, iii) a group in which at least one T4 group is condensed with at least one T1 group, iv) a group in which at least one T4 group is condensed with at least one T3 group, or v) a group in which at least one T4 group, at least one T1 group, and at least one T3 group are condensed (for example, the π electron-deficient nitrogen-containing C₁-C₆₀ cyclic group may be a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and/or the like),
wherein the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,
the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,
the T3 group may be a furan group, a thiophene group, a 1H-pyrrole group, a silole group, or a borole group, and
the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “π electron-rich C₃-C₆₀ cyclic group”, and/or “π electron-deficient nitrogen-containing C₁-C₆₀ cyclic group” as used herein may be a group condensed with any suitable cyclic group, a monovalent group, or a polyvalent group (e.g., a divalent group, a trivalent group, a quadvalent group, and/or the like), depending on the structure of the formula to which the term is applied. For example, a “benzene group” may be a benzene ring, a phenyl group, a phenylene group, and/or the like, and this may be understood by one of ordinary skill in the art, depending on the structure of Formula including the “benzene group”.

In some embodiments, examples of the monovalent C₃-C₆₀ carbocyclic group and monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group having 1 to 60 carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an iso-nonyl group, a sec-nonyl group, a tert-nonyl group, an n-decyl group, an isodecyl group, a sec-decyl group, and a tert-decyl group.

The term “C₁-C₆₀ alkylene group” as used herein refers to a divalent group having substantially the same structure as the C₁-C₆₀ alkyl group.

The term “C₂-C₆₀ alkenyl group” as used herein refers to a hydrocarbon group having at least one carbon-carbon double bond in the middle and/or at the terminus of the C₂-C₆₀ alkyl group. Examples thereof may include an ethenyl group, a propenyl group, and a butenyl group. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle and/or at the terminus of the C₂-C₆₀ alkyl group. Examples thereof may include an ethynyl group and a propynyl group. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by —OA₁₀₁ (wherein A₁₀₁ is a C₁-C₆₀ alkyl group). Examples thereof include a methoxy group, an ethoxy group, and an isopropyloxy group.

The term “C₃-C₁₀ cycloalkyl group” as used herein refers to a monovalent saturated hydrocarbon monocyclic group including 3 to 10 carbon atoms. Examples of the C₃-C₁₀ cycloalkyl group as used herein include a cyclopropyl group, a cyclobutyl group, a cyclopentyl group, a cyclohexyl group, a cycloheptyl group, a cyclooctyl group, an adamantanyl group, a norbornanyl (bicyclo[2.2.1]heptyl) group, a bicyclo[1.1.1]pentyl group, a bicyclo[2.1.1]hexyl group, or a bicyclo[2.2.2]octyl group.

The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group including at least one heteroatom other than carbon atoms as a ring-forming atom and having 1 to 10 carbon atoms. Examples thereof may include a 1,2,3,4-oxatriazolidinyl group, a tetrahydrofuranyl group, and a tetrahydrothiophenyl group. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms and at least one carbon-carbon double bond in its ring, and is not aromatic when the molecular structure is considered as a whole. Examples thereof may include a cyclopentenyl group, a cyclohexenyl group, and a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group including at least one heteroatom other than carbon atoms as a ring-forming atom, 1 to 10 carbon atoms, and at least one double bond in its ring. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system having 6 to 60 carbon atoms. The term “C₆-C₆₀ arylene group” as used herein refers to a divalent group having substantially the same structure as the C₆-C₆₀ aryl group. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each independently include two or more rings, the respective rings may be fused.

The term “C₁-C₆₀ heteroaryl group” as used herein refers to a monovalent group having a heterocyclic aromatic system further including at least one heteroatom other than carbon atoms as a ring-forming atom and 1 to 60 carbon atoms. The term “C₁-C₆₀ heteroarylene group” as used herein refers to a divalent group having substantially the same structure as the C₁-C₆₀ heteroaryl group. Examples of the C₁-C₁₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each independently include two or more rings, the respective rings may be fused.

The term “monovalent non-aromatic condensed polycyclic group” as used herein refers to a monovalent group that has two or more condensed rings and only carbon atoms (e.g., 8 to 60 carbon atoms) as ring forming atoms, wherein the molecular structure when considered as a whole is non-aromatic. Examples of the monovalent non-aromatic condensed polycyclic group may include an indenyl group, a fluorenyl group, a spiro-bifluorenyl group, a benzofluorenyl group, an indenophenanthrenyl group, and an indenoanthracenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group that has two or more condensed rings and at least one heteroatom other than carbon atoms (e.g., 1 to 60 carbon atoms), as a ring-forming atom, wherein the molecular structure when considered as a whole is non-aromatic. Examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzooxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein refers to —OA₁₀₂ (wherein A₁₀₂ is a C₆-C₆₀ aryl group). The term “C₆-C₆₀ arylthio group” as used herein refers to —SA₁₀₃ (wherein A₁₀₃ is a C₆-C₆₀ aryl group).

The term “C₇-C₆₀ aryl alkyl group” as used herein refers to -A₁₀₄A₁₀₅ (wherein A₁₀₄ is a C₁-C₅₄ alkylene group, and A₁₀₅ is a C₆-C₅₉ aryl group). The term “C₂-C₆₀ heteroaryl alkyl group” as used herein refers to -A₁₀₆A₁₀₇ (wherein A₁₀₆ is a C₁-C₅₉ alkylene group, and A₁₀₇ is a C₁-C₅₉ heteroaryl group).

The term “R₁₀ₐ” as used herein may be:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), S(═O)₂(Q₂₁), —P(═O)(Q₂₁)(Q₂₂), or any combination thereof; or
Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ may each independently be: hydrogen; deuterium; —F; —CI; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ aryl alkyl group; or a C₂-C₆₀ heteroaryl alkyl group.

The term “heteroatom” as used herein refers to any atom other than a carbon atom. Examples of the heteroatom may include O, S, N, P, Si, B, Ge, Se, and any combination thereof.

A third-row transition metal as used herein may include hafnium (Hf), tantalum (Ta), tungsten (W), rhenium (Re), osmium (Os), iridium (Ir), platinum (Pt), and/or gold (Au).

“Ph” used herein represents a phenyl group, “Me” used herein represents a methyl group, “Et” used herein represents an ethyl group, “ter-Bu” or “Bu^{t}” used herein represents a tert-butyl group, and “OMe” used herein represents a methoxy group.

The term “biphenyl group” as used herein refers to a phenyl group substituted with a phenyl group. The “biphenyl group” belongs to “a substituted phenyl group” having a “C₆-C₆₀ aryl group” as a substituent.

The term “terphenyl group” as used herein refers to a phenyl group substituted with a biphenyl group. The “terphenyl group” belongs to “a substituted phenyl group” having a “C₆-C₆₀ aryl group substituted with a C₆-C₆₀ aryl group” as a substituent.

The symbols * and *′ as used herein, unless defined otherwise, refer to a binding site to an adjacent atom in a corresponding formula or moiety.

Hereinafter, the method of preparing a quantum dot and the thus produced quantum dot according to one or more embodiments will be described in more detail with reference to Synthesis Examples and Examples.

### EXAMPLES

### Comparative Example 1: Preparation of AgGaS₂/GaS_{y} Quantum Dot

### Preparation of Core

In a reactor, 0.2 mmol of silver (Ag) iodide, 0.45 mmol of gallium (Ga) iodide, 2.5 mL of oleylamine (OLA), and 2.5 mL of 1-octadecane (ODE) were mixed together, followed by degassing at a temperature of 120° C. for 1 hour. After purging with nitrogen, 0.8 mL of S-OLA (1 M) and 0.45 mL of 1-dodecanethiol (DDT) were injected thereto. Next, the temperature of the reactor was heated up to 300° C. to maintain a core reaction for 10 minutes, followed by cooling to 180° C. 1 mL of trioctylphosphine (TOP) was injected thereto, followed by maintaining the reaction for 30 minutes. Then, the temperature was cooled to room temperature to thereby complete the reaction.

### Purification of Core

After mixing the synthesized core solution with 5 mL of n-hexane as a dispersion solvent, a centrifuge was used to remove unreacted substances. Subsequently, 20 mL of ethanol was injected thereto, and the core quantum dot was precipitated using a centrifuge. After repeating this process one more time, the purified core was dispersed in 1 mL of toluene and stored.

### Preparation of First Shell

After mixing 1.6 mmol of S with 8 mL of OLA in a reactor, 1.1 mL of gallium (Ga) chloride-toluene (2 M) and the core solution were injected thereto. Next, after degassing at 120° C. for 1 hour, the temperature was heated to 240° C., and the reaction was maintained for 1 hour. After cooling the reactor to 200° C., 0.5 mL of 1-octanethiol and 0.5 mL of TOP were injected thereto, and the reaction was maintained for 30 minutes. Subsequently, the temperature was cooled to room temperature, and the completed quantum dot was purified using n-hexane and ethanol to prepare the quantum dot of Comparative Example 1.

### Comparative Example 3: Preparation of AgInₓGa₁₋ₓS₂/GaS_{y} Quantum Dot

### Preparation of Core

In a reactor, 0.2 mmol of silver (Ag) iodide, 0.425 mmol of gallium (Ga) iodide, 0.025 mmol of indium (In) iodide, 2.5 mL of oleylamine (OLA), and 2.5 mL of 1-octadecane (ODE) were mixed together, followed by degassing at a temperature of 120° C. for 1 hour. After purging with nitrogen, 0.8 mL of S-OLA (1 M) and 0.45 mL of 1-dodecanethiol (DDT) were injected thereto. Next, the temperature of the reactor was heated up to 300° C. to maintain a core reaction for 10 minutes, followed by cooling to 180° C. 1 mL of TOP was injected thereto, followed by maintaining the reaction for 30 minutes. Then, the temperature was cooled to room temperature to thereby complete the reaction.

### Purification of Core and Preparation of First Shell

The purification of core and the purification of first shell were performed in substantially the same manner as in Comparative Example 1 to prepare the quantum dot of Comparative Example 3.

### Example 1: Preparation of AgInₓGa₁₋ₓS₂/Thick-GaS_{y} Quantum Dot

### Preparation and Purification of Core

The preparation and purification of the core in Example 1 were performed in substantially the same manner as in Comparative Example 3.

### Preparation of First Shell

After mixing 0.8 mmol of S with 8 mL of OLA in a reactor, 0.55 mL of gallium (Ga) chloride-toluene (2 M) and the core solution were injected thereto. Next, after degassing at 120° C. for 1 hour, the temperature was heated to 240° C., and the reaction was maintained for 30 minutes. 0.8 mL of S-OLA (1 M) and 0.55 mL of Ga-toluene (2 M) were injected thereto, followed by maintaining the reaction for 30 minutes. After repeating 2 times the injection process as described above, the reactor was cooled to 200° C., 0.5 mL of 1-octanethiol and 0.5 mL of TOP were injected thereto, and the reaction was maintained for 30 minutes. Subsequently, the temperature was cooled to room temperature, and the completed quantum dot was purified using n-hexane and ethanol.

### Example 2: Preparation of AgInₓGa₁₋ₓS₂/Thick-GaS_{y}/MgS Quantum Dot

### Preparation and Purification of Core

The preparation and purification of the core in Example 2 were performed in substantially the same manner as in Comparative Example 3.

### Preparation of First Shell and Second Shell

After mixing 0.8 mmol of S with 8 mL of OLA in a reactor, 0.55 mL of gallium (Ga) chloride-toluene (2 M) and the core solution were injected thereto. Next, after degassing at 120° C. for 1 hour, the temperature was heated to 240° C., and the reaction was maintained for 30 minutes. 0.8 mL of S-OLA (1 M) and 0.55 mL of Ga-toluene (2M) were injected thereto, followed by reaction for 30 minutes. Then, 1 mL of magnesium (Mg) stearate-oleic acid (OA)-ODE (0.5 M) and 0.5 mL of S-OLA (1 M) were injected thereto, followed by reaction for 30 minutes. After repeating 2 times the process as described above, the reactor was cooled to 200° C., 1 mL of 1-octanethiol and 1 mL of TOP were injected thereto, and the reaction was maintained for 30 minutes. Subsequently, the temperature was cooled to room temperature, and the completed quantum dot was purified using n-hexane and ethanol.

### Comparative Examples 2 and 3

Quantum dots were prepared in substantially the same manner as in Comparative Example 3, except that, in Preparation of core, a molar ratio of the first precursor to the second precursor was adjusted such that a molar ratio of In/(Ga+In) in the core of the quantum dots was as described in Table 2.

### Evaluation Example 1

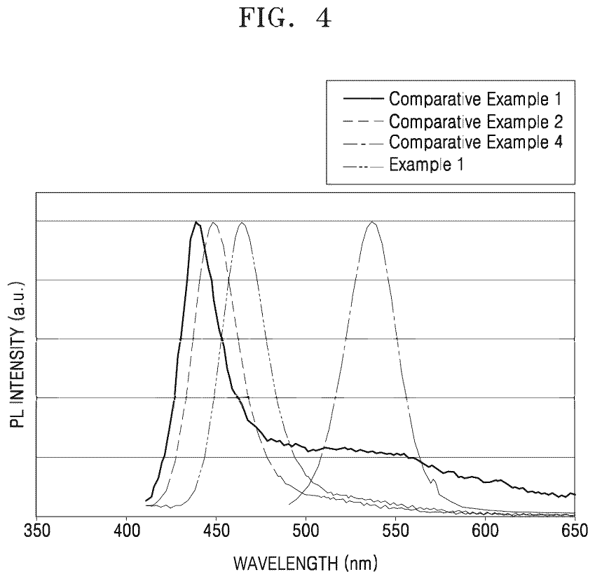

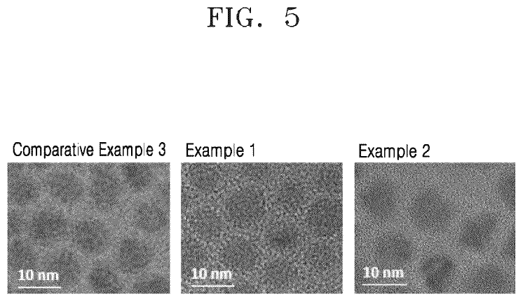

The photoluminescence spectra of Example 1 and Comparative Examples 1, 2, and 4 measured by using Otsuka QE-2100 are shown in FIG. 4.

The weight ratio of In to Ga in the core was measured by using inductively coupled plasma-mass spectrometer. The maximum emission wavelength (Amax, nm) of the photoluminescence spectra in FIG. 4 are shown in Table 1.

TABLE 1

| | | λₘₐₓ |
|---|---|---|
| | Molar ratio (%) of In/(Ga + In) | (nm) |
| Comparative | 0 | 438 |
| Example 1 | | |
| Comparative | 2.8 | 445 |
| Example 2 | | |
| Example 1 | 5.6 | 463 |
| Comparative | 44.4 | 537 |
| Example 4 | | |

Referring to FIG. 4 and Table 1, as a weight ratio (%) of In/(Ga+In) increases, the maximum emission wavelength was shifted to a longer maximum emission wavelength from 438 nm to 537 nm.

### Evaluation Example 2

The radius of the core and the thicknesses of the first shell and/or the second shell of each of the quantum dots in Examples 1 and 2 and Comparative Examples 1 to 4 were measured by using transmission electron microscopy (TEM) analysis. The results thereof are shown in Table 2, and the related image regarding Examples 1 and 2 and Comparative Example 3 is shown in FIG. 5.

370 nm excitation was performed by using Otsuka QE-2100, and at absorption of 0.4, the photoluminescence spectra of all of the quantum dots were measured. Thus, the peak wavelength, full width at half maximum (FWHM), and photoluminescence quantum yield (PLOY) in the photoluminescence spectra were measured. The results thereof are shown in Table 2.

TABLE 2

| | Molar | | | | | | |
|---|---|---|---|---|---|---|---|
| | ratio | Thickness | | | | | Full |
| | (%) | | Thickness | Thickness | Peak | | width |
| | of | Radios | of | of | wavelength of | | at half |
| | In/( | of | first | second | photoluminescence | Luminescence | maximum |
| | Ga + | core | shell | shell | spectrum | efficiency | (FWHM) |
| | In) | (nm) | (nm) | (nm) | (nm) | (%) | (nm) |
| Comparative | 0 | 5 | 0.5 | — | 438 | 10 | 28 |
| Example 1 | | | | | | | |
| Comparative | 2.8 | 5 | 0.5 | — | 445 | 14 | 28 |
| Example | | | | | | | |
| 2 | | | | | | | |
| Comparative | 5.6 | 5 | 0.5 | — | 464 | 35 | 30 |
| Example | | | | | | | |
| 3 | | | | | | | |
| Comparative | 44.4 | 5 | 1.1 | — | 537 | — | — |
| Example | | | | | | | |
| 4 | | | | | | | |
| Example 1 | 5.6 | 5 | 1.1 | — | 463 | 45 | 30 |
| Example 2 | 5.6 | 5 | 1.1 | 0.2 | 460 | 51 | 31 |

Referring to Table 2, the quantum dots of Examples 1 and 2 were found to have improved luminescence efficiency, as compared with the quantum dots of Comparative Examples 1 to 3, and the peak wavelength of photoluminescence spectrum in Comparative Example 4 was 537 nm, which is different from those of Examples 1 and 2.

As apparent from the foregoing description, when the quantum dot according to one or more embodiments includes a core having a certain size according to the present embodiments and a first shell having a certain thickness according to the present embodiments, defects on a surface of the core may be effectively (or suitably) suppressed or reduced, and thus, stability may be maintained while having excellent or improved luminescence efficiency and narrow FWHM. Therefore, the quantum dot may be used as a blue light source to thereby provide an optical member and an electronic apparatus with high quality.

In the present specification, when particles are spherical, “radius” indicates a particle radius, and when the particles are non-spherical, the “radius” indicates one-half (½) of a major axis length.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims and their equivalents.

What is claimed is:

1. A quantum dot comprising:
a core comprising indium (In) and A¹; and
a first shell covering the core,
wherein
A¹ is a group III element other than indium,
a ratio of a radius of the core to a thickness of the first shell is in a range of about 1:1 to about 9:1, and
the quantum dot is configured to emit blue light having a maximum emission wavelength in a range of about 440 nanometers (nm) to about 480 nm.

2. The quantum dot of claim 1, wherein
the core further comprises A² and B¹,
A² is a group I element, and
B¹ is a group VI element.

3. The quantum dot of claim 1, wherein a content of indium in the core is greater than 0 parts by mass and about 30 parts by mass or less, based on 100 parts by mass of indium and A¹ in the core.

4. The quantum dot of claim 1, wherein the core comprises a first semiconductor compound represented by Formula 1:
A²InₓA¹₁₋ₓB¹₂, and Formula 1
wherein, in Formula 1,
A¹ is a group III element other than indium,
A² is a group I element,
B¹ is a group VI element, and
x is an integer greater than 0 and smaller than 1.

5. The quantum dot of claim 1, wherein
the first shell comprises A³ and B²,
A³ is a group III element, and
B² is a group VI element.

6. The quantum dot of claim 5, wherein A¹ and A³ are identical to each other.

7. The quantum dot of claim 1, wherein the first shell comprises a second semiconductor compound represented by Formula 2:
A³B²_{y}, and Formula 2
wherein, in Formula 2,
A³ is a group III element,
B² is a group VI element, and
y is an integer from 0.5 or greater and 2 or lower.

8. The quantum dot of claim 1, further comprising a second shell covering the first shell.

9. The quantum dot of claim 8, wherein
the second shell comprises A⁴ and B³,
A⁴ is a group II element, and
B³ is a group VI element.

10. The quantum dot of claim 8, wherein the second shell comprises a third semiconductor compound represented by Formula 3:
A⁴B³, and Formula 3
wherein, in Formula 3,
A⁴ is a group II element, and
B³ is a group VI element.

11. The quantum dot of claim 8, wherein a thickness ratio of the first shell to the second shell is in a range of about 1:1 to about 6:1.

12. The quantum dot of claim 1, wherein a radius of the core is in a range of about 3 nm or greater and about 10 nm or less.

13. The quantum dot of claim 1, wherein a thickness of the first shell is greater than about 0.5 nm and 4 nm or less.

14. An optical member comprising the quantum dot according to claim 1.

15. An electronic apparatus comprising the quantum dot of claim 1.

16. The electronic apparatus of claim 15, further comprising:
a light source; and
a color conversion member on a pathway of light emitted from the light source,
wherein the quantum dot is comprised in the color conversion member.

17. The electronic apparatus of claim 15, further comprising: a light-emitting device comprising:
a first electrode; a second electrode facing the first electrode; and an emission layer between the first electrode and the second electrode,
wherein the quantum dot is comprised in the light-emitting device.

18. A method of preparing quantum dots, the method comprising:
mixing a first precursor comprising indium (In) with a second precursor comprising A¹ to prepare a core; and
mixing a third precursor comprising A³ with a fourth precursor comprising B² to prepare a first shell,
wherein A¹ is a group III element other than indium, A³ is a group III element, B² is a group VI element, and a molar ratio of the second precursor to the third precursor is 1:5.2 or greater.

19. The method of claim 18, wherein a content of indium in the first precursor is greater than 0 parts by mass and about 30 parts by mass or less, based on 100 parts by mass of indium in the first precursor and A¹ in the second precursor.

20. The method of claim 18, further comprising, after preparing of the first shell, mixing a fifth precursor comprising A⁴ with a sixth precursor comprising B³ to prepare a second shell,
wherein A⁴ is a group II element, and B³ is a group VI element.
